(19) United States
(12) Patent Application Publication
(10) Pub. No.: US 2026/0271222 A1
(43) Pub. Date: Sep. 10, 2026

(54) HEAT DISSIPATING FAN WITH A DISPLAY SCREEN

(71) Applicant: Shenzhen Delis Electronic Technology Co., Ltd., Shenzhen City (CN)

(72) Inventor: Hong Min Li, Mozhou City (CN)

(21) Appl. No.: 19/390,555

(22) Filed: Nov. 15, 2025

(30) Foreign Application Priority Data
Mar. 10, 2025 (CN) 202520402262.4

(51) Int. Cl. H05K 7/20

(52) U.S. Cl. CPC H05K 7/20172

(57) ABSTRACT

The invention discloses a cooling fan with an integrated display screen. The fan includes a lower frame, motor rotor, upper frame, fan rotor, bearing assembly, fastening assembly, and a display screen assembly. A central base in the lower frame supports a sleeve containing a cylindrical positioning piece with an upper through hole. The display screen assembly includes a metal fixing piece, a display screen PCB set, and a lower cover. An axis arranged at the center of the PCB set penetrates the display screen assembly, fan rotor, fastening assembly, and bearing assembly, and is inserted into the through hole of the positioning piece. The display screen PCB set is embedded in a fan groove, enabling visual monitoring of fan speed and cooling performance, while the structural arrangement provides stable, simple installation and reduced operating noise.

### TECHNICAL FIELD

The present invention relates to a heat dissipating fan, and more particularly, to a heat dissipating fan having a display screen.

### BACKGROUND

The CPU, power supply, etc. are typically housed in a cabinet. The heat generated by the CPU, power supply, etc. during operation of the equipment may be undesirably dissipated from the cabinet. This results in the temperature in the cabinet increasing, which may affect the efficiency of the operation of the equipment. Consequently, heat dissipating fans are typically installed in front, back, top, and bottom panels of the cabinet. Accordingly, appropriate air ducts are provided to dissipate the heat in the cabinet in a timely manner to maintain a relatively proper temperature inside the cabinet.

The known cooling fan is basically a fan frame and a fan blade. The cooling fan is mounted in a casing and rotates at a certain speed, which ensures that the heat in the casing is discharged. However, the user cannot intuitively obtain the specific speed of the cooling fan, and the heat dissipating effect caused by the fan, i.e. the real-time temperature in the casing. If it is desired to know the specific speed of the fan and the temperature in the casing, it is only obtained by installing corresponding software in a computer. This is not straightforward. The installation and opening of the software increases the operating time and the problems of unstable bearings and noisy assembly of the known cooling fan bearings and the shaft core affect the life and the experience.

### DISCLOSURE OF INVENTION

The present invention aims to provide a heat dissipating fan with a display screen, in order to solve the problems that the heat dissipating fan proposed in the above-mentioned background art cannot visually display the heat dissipating temperature on the surface of the fan body in real time and the deterioration of the life and noise caused by the unstable bearing and hub assembly.

In order to accomplish the above object, according to the present invention, there is provided a heat dissipating fan with a display screen, comprising: a lower frame having a base at the center thereof and a sleeve at the center thereof, a cylinder positioning member at the center thereof, a through hole being formed at the center of the sleeve, a motor rotor having a through hole formed at the center of the cylinder positioning member; and an upper frame having a hollowed-out annular through hole uniformly distributed around the surface thereof; The fan rotor has a groove at its inner portion; a bearing assembly composed of a spacer, a first ball bearing, a second ball bearing, and a spring; a fastener assembly composed of a fastener, a metal fastener, and a metal retaining ring; a monitor screen assembly composed of a metal fixing piece, a monitor screen PCB assembly, a monitor screen lower cover, and a monitor screen PCB assembly having a center with an axis, which in turn passes through the monitor screen lower cover, the metal fixing piece, the fan rotor, the fastener assembly, and the bearing assembly and is snap-fitted through a cylindrical spacer hole; the spacer is inserted in the sleeve through the cylindrical spacer hole; the first ball bearing is inserted in the sleeve through the cylindrical spacer hole and is positioned above the spacer; the spring is inserted in the sleeve through the cylindrical spacer hole and is positioned above the first ball bearing; the second ball bearing is inserted in the sleeve through the cylindrical spacer hole and is positioned above the spring; the fastener is inserted in the sleeve through the cylindrical spacer hole; the metal fastener is positioned above the second ball bearing and is snap-fitted with the metal fastener; the metal retaining ring is inserted in the upper portion of the metal fastener; the metal screen fixing piece is inserted in the fan rotor groove through the metal retaining ring; the monitor screen lower cover is inserted in the fan rotor groove through the metal fastener and is positioned above the metal fixing piece; the monitor screen PCB assembly is inserted in the fan rotor groove and is positioned above the monitor screen lower cover; and the monitor screen PCB assembly has a top surface with a monitor screen.

Preferably, said motor rotor is snap-fitted to its base through said sleeve, said motor rotor being peripherally fitted with an annular light band.

Preferably, there is further provided a light guide member, wherein the upper and lower top surface projections of the light guide member each have a tab.

Preferably, the light guide is at least four, and the bottom earclasps of the light guide are secured around the inner surface of the lower frame.

Preferably, the light guide top earhook is shaped to fit into the annular through hole so as to be received therein.

Preferably, there are further provided foot pads evenly distributed snap around the bottom of the lower frame and the top surface of the upper frame.

Preferably, the footing is at least 8 and the upper and lower frames are symmetrically and evenly distributed.

Preferably, there is further included a screen upper cover, said screen upper cover being fitted over the outside of the screen assembly, said screen upper cover being fitted in a shape of a fan rotor boss to snap-fit with the groove.

Preferably, the upper and lower frames are shaped to be snap fitted.

As compared with the prior art, the present invention has the advantage that the present invention can be easily and reliably installed by mounting the first ball bearing and the second ball bearing in cooperation with the spring and the fastener around the outside thereof so that the fan can be rotated in use with less noise, and the display screen PCB assembly is inserted in the fan groove, and the fan rotation speed and heat dissipation can be seen more intuitively and the shaft is inserted through the display screen assembly, the fan rotor, the fastener assembly and the bearing assembly and fixed in its interior by the cylindrical spacer through-hole.

### BRIEF DESCRIPTION OF THE DRAWINGS

FIG. 1 is a schematic view showing the overall construction of a heat dissipating fan having a display screen according to the present invention;

FIG. 2 is an exploded view showing the overall structure of a heat dissipating fan having a display screen according to the present invention;

FIG. 3 is a perspective view of a sleeve structure of a heat dissipating fan according to the present invention having a display screen;

FIG. 4 is a schematic view of a light guide of a heat dissipating fan having a display screen according to the present invention.

FIG. 5 is a schematic view illustrating a foot bed in a heat dissipating fan having a display screen according to the present invention.

In the drawings: 1. Screen cover; 2. Screen assembly; 3. Fan rotor; 4. Motor rotor; 5. Bearing assembly; 6. Lower frame; 7. Upper frame; 8. Fastener assembly; 201. Screen PCB set; 202. Screen cover lower; 203. Metal fixing piece; 2011. Axle; 2012. Screen; 301. Grooves; 401. Annular light band; 501. Metal retaining ring; 502. Metal retaining ring; 507. Fastener; 503. Second ball bearing; 504. Spring; 505. First ball bearing; 506. Spacer; 601. Base; 602. Light guide; 6011. Sleeve; 6012. Cylindrical spacer; 6013. Through hole; 6021. Earring; 701. Foot pad.

### DETAILED DESCRIPTION

The present invention is described in detail below with reference to the accompanying drawings, in which embodiments of the invention are shown. It is to be understood that the embodiments described are merely some of the embodiments of the invention, and not all embodiments of the invention. Based on the embodiments of the invention, a person of ordinary skill in the art would realize that all other embodiments of the invention are possible without creative efforts.

In describing the present invention, it is noted that terms such as “central”, “upper”, “lower”, “left”, “right”, “vertical”, “horizontal”, “inner”, “outer”, and the like refer to orientations or positional relationships as are set forth in the drawing figures only for ease of description of the present invention and ease of description, and do not indicate or imply that the device or element must be oriented or configured and operated in a particular orientation and, therefore, should not be considered as limiting. Further, the terms first “,” second”, and third are used for descriptive purposes only and should not be construed as indicating or implying relative importance. In describing the present invention, it is noted that the terms “mounted”, “connected”, and “disposed” are to be broadly construed and interpreted, for example, as fixed or removable or integrally connected, as well as mechanically or electrically connected, as directly connected or indirectly connected through intervening media, as well as inter-proximal communication between two elements unless expressly specified or limited otherwise. The terms so defined have their ordinary meaning in the context of this disclosure. The present invention is illustrated by the following figures, and examples thereof, in terms of its overall structure.

### EXAMPLES

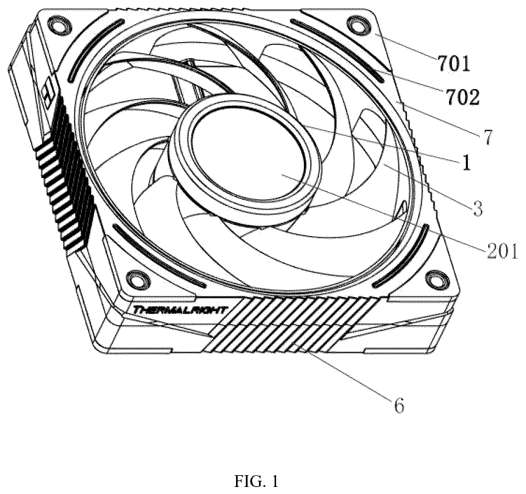

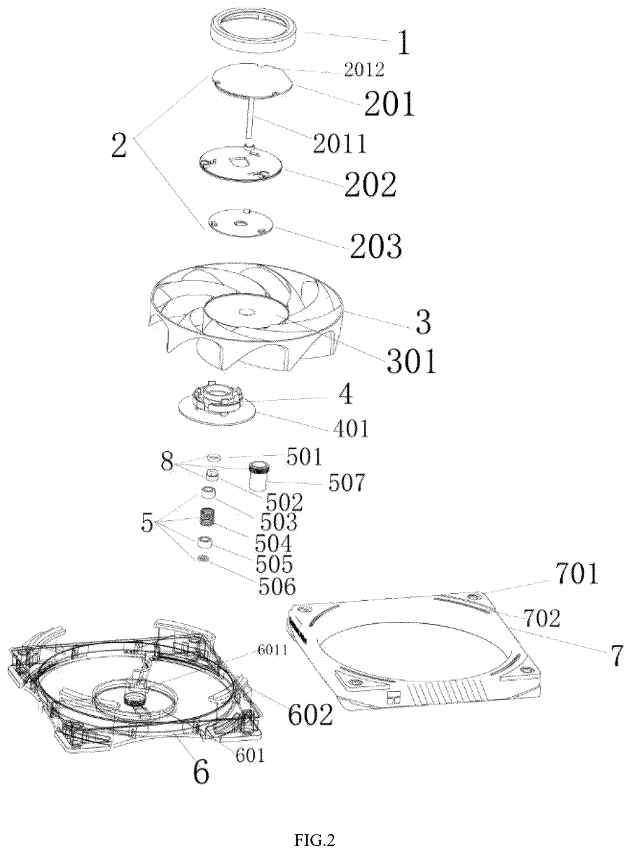

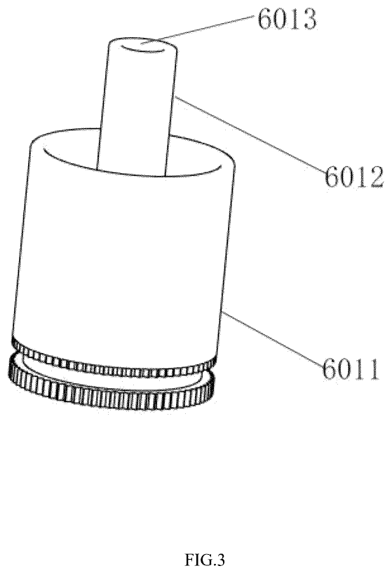

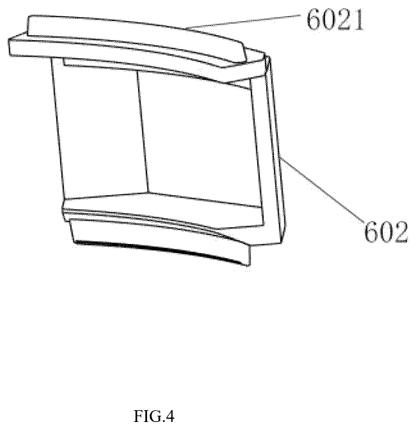

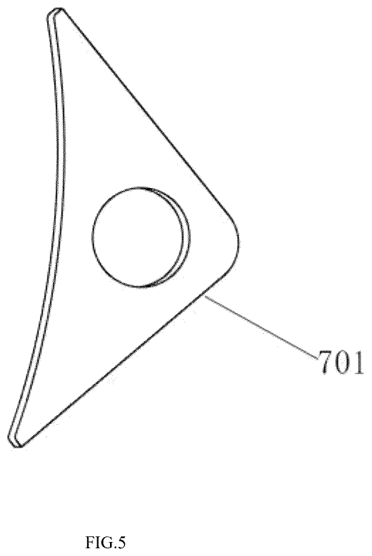

Referring to FIGS. 1 to 5, a display-screen heat dissipating fan according to the present invention comprises: a lower frame 6 including a base 601 formed at the center thereof, a sleeve 6011 formed at the center thereof, a cylindrical locating member 6012 formed at the interior thereof, and a through hole 6013 formed at the upper surface thereof; a motor rotor 4; an upper frame 7 including a hollowed-out annular through hole 702 uniformly distributed around the surface thereof; a fan rotor 3 including a groove 301 formed at the inner surface thereof; a bearing assembly 5 including a spacer 506, a first ball bearing 505, a second ball bearing 503, and a spring 504; a fastening assembly 8 including a fastener 507, a metal buckle 502, and a metal buckle 501; a display-screen assembly 2 including a metal fixing piece 203, a display-screen PCB assembly 201, and a display-screen lower cover 202, and including an axial center 2011 which is inserted through the display-screen lower cover 202, the metal fixing piece 203, the fan rotor 3, the fastening assembly 8, and the bearing assembly 5 in turn and secured through the cylindrical locating member through hole 6013; and the spacer 506 is inserted through the cylindrical locating member through hole 6013 in the sleeve 6011, the first ball bearing 505 is inserted through the cylindrical locating member through hole 6013 in the sleeve 6011 and positioned above the spacer 506, the spring 504 is inserted through the cylindrical locating member through hole 6013 in the sleeve 6011 and positioned above the first ball bearing 505, the second ball bearing 503 is inserted through the cylindrical locating member through hole 6013 in the sleeve 6011 and positioned above the spring 504, the fastener 507 is inserted through the cylindrical locating member through hole 6013 in the sleeve 6011 and positioned around the bearing assembly 5 and inserted through the cylindrical locating member 6012 in the sleeve 6011, the metal buckle 502 is positioned above the second ball bearing 503 and secured to it, the metal buckle 501 is inserted through the metal buckle 502 at the upper portion thereof to make it stronger, and the metal screen fixing piece 203 is inserted through the metal buckle in the fan rotor groove 301, the display-screen lower cover 202 is inserted through the metal buckle in the fan rotor groove 301 and positioned above the metal fixing piece 203, the display-screen PCB assembly 201 is inserted through the fan rotor groove 301 and positioned above the display-screen lower cover 202, and including a display screen 2012 at the top surface thereof.

In this embodiment, it is preferable that the motor rotor 4 is snap-fitted through the sleeve 6011 to be fixed to its base 601 and the periphery of the motor rotor is further provided with an annular light band 401.

In the present embodiment, it is preferred to further include light guiding members 602, each provided with a protruding upper and lower top surface. The light guiding members 602 are provided with at least four locking members 602, the bottom locking members 602 are configured to be snap-fitted around the inner surface of the lower frame 6, and the top locking members 602 are configured with annular through holes 702 to be inserted therein.

In this embodiment, it is preferable to further comprise footings 701 which are fitted with an even distribution around the bottom of the lower frame 6 and the top surface of the upper frame 7, the footings 701 being provided with an even distribution of at least 8 and the upper and lower frames being symmetrically arranged.

In this embodiment, the display screen cover 1 is preferably provided externally of the display screen assembly 2, and is shaped to fit into the fan rotor groove 301 to snap-fit into the groove 301.

In this embodiment, the upper frame 7 and the lower frame 6 are preferably shaped to fit in a snap fit.

The present invention is based on the principle that the bearing assembly 5 is inserted into the sleeve through the through-hole 6013 of the cylindrical spot part during the operation, the fastener 507 is fitted into the outer part of the sleeve so as to be fixed while the metallic fastener 502 is snap-fitted into the upper part of the second ball bearing 503, and the metallic fastener 502 is fitted into the sleeve with the metallic fastener 501, so that the fan rotates with less stable and firm noise, and the display screen assembly 2 is inserted into the fan rotor groove 301, when the display screen PCB assembly upper core 2011 is inserted through the display screen lower cover 202, the metallic fixing piece 203, the fan rotor 3, the fastening members 8 and the bearing assembly 5 in turn and is snap-fitted through the through-hole 6013 of the cylindrical spot part, and the light guide 602 is snap-fitted into the inner surface of the lower frame, and the upper and lower frames 7 and 6 are fitted into the sleeve. Meanwhile, the display screen PCB assembly 201 is provided with the control circuit, the control circuit and the motor 4 and the light guide 401 are electrically connected with the power supply line, the power is turned on during the operation, the motor rotor 4 drives the fan rotor 3 to rotate, the chip in the control circuit, the sensor in real time displays the temperature of heat dissipation on the display screen 2012 and the light guide is illuminated, and the light guide 602 is snap-fitted into the lower and upper frames 6 and 7, so that the annular light guide 401 is illuminated and the light guide 602 is diffused and illuminated by the light guide 602, resulting in a better visual experience.

While the invention has been described in detail in the foregoing description, it is to be understood that the invention is not limited thereto. Those skilled in the art to which the invention pertains will readily appreciate that alterations and modifications of the disclosed embodiment or exemplary embodiments without departing from the spirit and scope of the invention.

What is claimed is:

1. A heat dissipating fan with a display screen, comprising:
a lower frame (6) which is provided at its center with a base (601) and at its middle with a sleeve (6011) and inside which a cylindrical retainer (6012) is provided, above which a through hole (6013) is provided;
a motor rotor (4);
an upper frame (7) which is provided with a hollow annular through hole (702) which is uniformly distributed around its surface;
a fan rotor (3) which is provided at its middle with a groove (301);
a bearing assembly (5) which is composed of a washer (506), a first ball bearing (505), a second ball bearing (503), and a spring (504);
a fastening assembly (8) which is composed of a fastening member (507), a metal buckle (502), and a metal buckle (501);
a display screen assembly (2) which is composed of a metal fixing plate (203), a display screen PCB set (201), a display screen cover (202), and at its center with a shaft (2011) which is provided at its center with a shaft which is provided in turn through the display screen cover (202), the metal fixing plate (203), the fan rotor (3), the fastening assembly (8), and the bearing assembly (5) and is fastened by plugging through the through hole (6013) of the cylindrical retainer; characterized in that the washer (506) is embedded in the sleeve (6011) through the through hole (6013) of the cylindrical retainer, the first ball bearing (505) is embedded in the sleeve (6011) through the through hole (6013) of the cylindrical retainer and above the washer (506), the spring (504) is embedded in the sleeve through the through hole (6013) of the cylindrical retainer and above the first ball bearing (505), the second ball bearing (503) is embedded in the sleeve through the through hole (6013) of the cylindrical retainer and above the spring (504), the fastening member (507) is fitted outside the bearing assembly (8) and embedded in the sleeve (6011) through the cylindrical retainer (6012), the metal buckle (502) is positioned above the second ball bearing (503) and fastened in its snap connection, the metal buckle (501) is fitted over the metal buckle (502), the metal fixing plate (203) is embedded in the fan rotor groove (301) through the metal buckle (501), the display screen cover (202) is embedded in the fan rotor groove (301) through the metal buckle (502) and above the metal fixing plate (203), the display screen PCB set (201) is embedded in the fan rotor groove (301) and above the display screen cover (202), and the display screen PCB set (201) is provided at its top surface with a display screen (2012).

2. A display-enabled heat-dissipating fan as claimed in claim 1, wherein said motor rotor (4) is snap-fitted on its base (601) through said sleeve (6011), said motor rotor being peripherally provided with an annular lamp band (401).

3. A display-enabled heat-dissipating fan as claimed in claim 1, further comprising light guides (602) provided with a key (6021) on upper and lower top surface protrusions, respectively.

4. A display-enabled heat-dissipating fan as claimed in claim 3, wherein said light guides (602) are at least four in number, said light guides being snap-fitted around the inner surface of the lower frame.

5. A display-enabled heat-dissipating fan as claimed in claim 4, wherein said light guides are shaped to fit into said annular through hole (702) in order to be embedded therein.

6. A display-enabled heat-dissipating fan as claimed in claim 1, further comprising footpads (701) uniformly distributed to be snap-fitted around the bottom of said lower frame (6) and the top surface of the upper frame (7).

7. A display-enabled heat-dissipating fan as claimed in claim 6, wherein said footpads (701) are at least eight and are symmetrically uniformly distributed on the upper and lower frames.

8. A display-enabled heat-dissipating fan as claimed in claim 1, further comprising a display-enabled cover (1) provided around the periphery of the display-enabled assembly (2), said display-enabled cover (1) being shaped to fit into the recess (301) of the fan rotor.

9. A display-enabled heat-dissipating fan as claimed in claim 1, wherein said upper frame (7) and said lower frame (6) are shaped to fit into each other.
